(19) United States
(12) Patent Application Publication
(10) Pub. No.: US 2026/0223351 A1
(43) Pub. Date: Jul. 30, 2026

(54) METHOD FOR FORMING CELL CONTACT OF MEMORY DEVICE

(71) Applicant: MICRON TECHNOLOGY, INC., BOISE, ID (US)

(72) Inventors: Kunihiro TSUBOMI, Hiroshima (JP); Shigeyuki YAHIRO, Hiroshima (JP); CHUN CHAO CHANG, Hiroshima (JP)

(73) Assignee: MICRON TECHNOLOGY, INC., BOISE, ID (US)

(21) Appl. No.: 19/455,276

(22) Filed: Jan. 21, 2026

Related U.S. Application Data
(60) Provisional application No. 63/750,903, filed on Jan. 29, 2025.

(51) Int. Cl. H10B 12/00

(52) U.S. Cl. CPC H10B 12/0335; H10B 12/315; H10B 12/485; H10B 12/50

(57) ABSTRACT

Some embodiments of the disclosure provide a method for forming cell contacts of a memory device, the method comprising forming two layers in a plurality of gaps for separation of cell contacts, wherein the two layers include a first layer on surfaces of the gaps and a second layer on the first layer, the second layer filling the gaps covered by the first layer. The second layer separates cell contacts formed in cell contact halls from each other. The method effectively achieves sufficient separation of the cell contacts while at the same time achieving the sufficient cell contacts size to prevent or mitigate defects due to high resistance of the cell contacts.

### CROSS-REFERENCE TO RELATED APPLICATIONS

This application claims the filing benefit of U.S. Provisional Application No. 63/750,903, filed January 29, 2025. This application is incorporated by reference herein in its entirety and for all purposes.

### BACKGROUND

High data reliability, high speed of memory access, low power consumption, and reduced chip size are some features that are demanded from semiconductor memory devices, such as a dynamic random-access memory (DRAM). A memory device may include a plurality of memory cells located at intersections of word lines and bit lines. Each memory cell may include a capacitor to store data and a transistor to access the capacitor. A memory cell capacitor may be coupled to one of source and drain of an associated memory cell transistor formed in active regions of a semiconductor substrate by a cell contact and a redistribution layer (RDL). A cell contact may be a conductive contact that is coupled to one of source/drain regions in the semiconductor substrate at one end and to an RDL at another end. The RDL is further coupled to an associated memory cell capacitor. The cell contact may thus be formed to couple the cell capacitor to the one of the source/drain regions in the semiconductor substrate via the corresponding RDL.

### BRIEF DESCRIPTION OF THE DRAWINGS

FIGS. 1A-1D to 16A-16D depict processes of an example method of forming at least part of a cell contact of a memory device in a plan view and a cross-sectional view according to some embodiments of the disclosure.

FIG. 17 depicts a block diagram of a memory device including a memory region and a peripheral region in a plan view according to some embodiments of the disclosure.

### DETAILED DESCRIPTION

Various example embodiments of the disclosure and combinations thereof will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for ease of illustration. In the drawings, the dimensions and dimensional ratios of each unit do not necessarily match the actual dimensions and dimensional ratios in the embodiments.

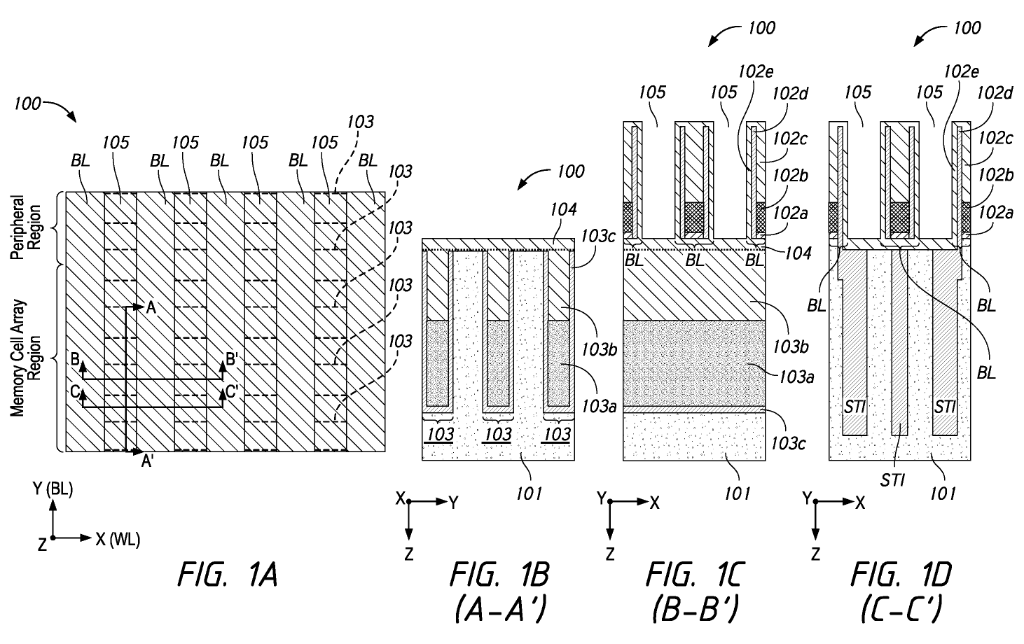

FIGS. 1A-1D to 16A-16D depict processes of an example method of forming at least part of a cell contact of a memory device 100 in a plan view and a cross-sectional view according to some embodiments of the disclosure. FIGS. 1A-16A depict the processes in the plan view. FIGS. 1B-16B depict the processes in the cross-sectional view at line A-A’ of FIGS. 1A-16A. FIGS. 1C-16C depict the processes in the cross-sectional view at line B-B’ of FIGS. 1A-16A. FIGS. 1D-15D depict the processes in the cross-sectional view at line C-C’ of FIGS. 1A-16A. The memory device 100 may be a dynamic random-access memory (DRAM). The memory device 100 may be one example of a semiconductor device. The memory device 100 may be one example of an apparatus. The memory device 100 includes a memory cell array region and a peripheral region on a semiconductor substrate 101, such as a silicon substrate. The memory cell array region may include a plurality of memory cells arranged at intersections of word lines and bit lines. Bit lines (or digit lines) may be arranged in parallel with each other in a first horizontal direction, which may be for example an X-axis direction in the drawing, and each may extend in a second horizontal direction, which may be for example a Y-axis direction in the drawing, orthogonal (or substantially orthogonal within reasonable tolerances of fabrication, measurement, etc.) to the first horizontal direction. Word lines may be arranged in parallel with each other in the Y-axis direction and each may extend in the X-axis direction. The X-axis direction and the Y-axis direction may also be referred to as a word line (WL) direction and a bit line (BL) direction, respectively. The memory cell array region may also include cell contacts CC that are coupled to active regions, such as source and drain regions, formed in the semiconductor substrate 101. The memory cell array region may further include redistribution layers RDL above the corresponding cell contacts CC and memory cell capacitors MCC above the corresponding redistribution layers RDL. The cell contacts CC couple the active regions of the semiconductor substrate 101 to the redistribution layers RDL. The redistribution layers RDL couple the cell contacts CC to the memory cell capacitors MCC. The active regions of the semiconductor substrate 101 and the memory cell capacitors MCC are thus coupled to each other by the cell contacts CC and the redistribution layers RDL. The cell contacts CC are formed in the memory cell array region to couple the cell capacitors MCCs to the active (source/drain) regions of the semiconductor substrate 101 via the redistribution layers RDL. The memory cell array region may include other elements as appropriate. The memory cell array region may have a square shape, a rectangular shape, or the like in a plan view (for example, in a plane along the X-axis direction and the Y-axis direction) on the semiconductor substrate 101. The peripheral region may be provided adjacent to the memory cell array region in the X-axis direction and/or the Y-axis direction. The peripheral region may be provided around the memory cell array region in the plan view on the semiconductor substrate 101.

As shown in FIGS. 1A-1D, a plurality of bit lines BL are formed on the semiconductor substrate 101 in the memory cell array region and the peripheral region. Each bit line BL may include a bit line structure, which may include a first conductive part 102a and a second conductive part 102b on the first conductive part 102a. The first conductive part 102a as a lower conductive part may include a conductive material, such as titanium nitride (TiN). The second conductive part 102b as an upper conductive part may include a conductive material, such as tungsten (W). On the second conductive part 102b is an insulating layer 102c including an insulating material, such as silicon nitride (SiN). The first conductive part 102a, the second conductive part 102b, and the insulating layer 102c may be part of the bit line structure BL. An insulating film 102d may be provided on side surfaces of the first and second conductive parts 102a and 102b and the insulating layer 102c. The insulating film 102d may include an insulating material, such as silicon oxide (SiO). Another insulating film 102e may be provided on the insulating film 102d. The insulating film 102e may include an insulating material, such as SiN, different from the insulating material of the insulating film 102d. The insulating films 102d and 102e may also be part of the bit line structure BL. In some embodiments, there may be other elements provided as part of or to the bit line structure BL as appropriate. In the depicted example, the plurality of bit line structures BL are arranged in parallel with each other in the X-axis direction and each extend in the Y-axis direction. A plurality of gaps or spaces 105 each exist between the neighboring bit line structures BL. Any conventional processes as well as conventional materials may be used for the formation of the bit line structures BL as appropriate. The semiconductor substrate 101 may include a shallow trench isolation (STI). The STI may include an insulating material, such as SiO. The semiconductor substrate 101 may include a gate electrode structure 103 of a memory cell transistor. The gate electrode structure 103 may include a gate electrode 103a, an insulating layer 103b, and a gate oxide film 103c. The gate electrode 103a may include for example polysilicon (poly-Si) or TiN. The insulating layer 103b may include for example SiN. The gate oxide film may include for example SiO. In some embodiments, there may be other elements provided as part of or to the gate electrode structure 103 as appropriate. In the depicted example, another insulating layer 104 is provided on top of the gate electrode structure 103. The insulating layer 104 may include for example SiN. In some embodiments, the insulating layer 103b of the gate electrode structure 103 and the insulating layer 104 may be formed together by the same process of for example deposition.

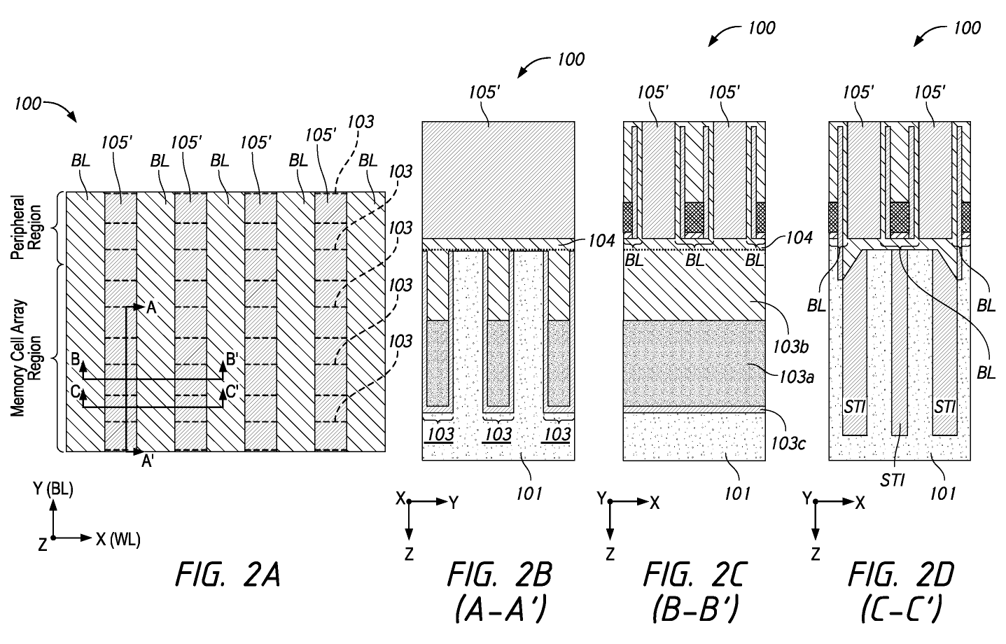

As shown in FIGS. 2A-2D, as part of cell contact formation, the plurality of gaps/spaces 105 each between the neighboring bit lines structures BL are filled with an oxide by for example deposition to form a plurality of oxide-filled gaps/spaces 105’. The oxide may include for example SiO. Any conventional processes as well as conventional oxide materials may be applicable for the gap fill as appropriate. Top surface of the oxide-filled gaps/spaces 105’ and the bit line structures BL may be smoothed and cleaned by for example chemical-mechanical polishing (CMP).

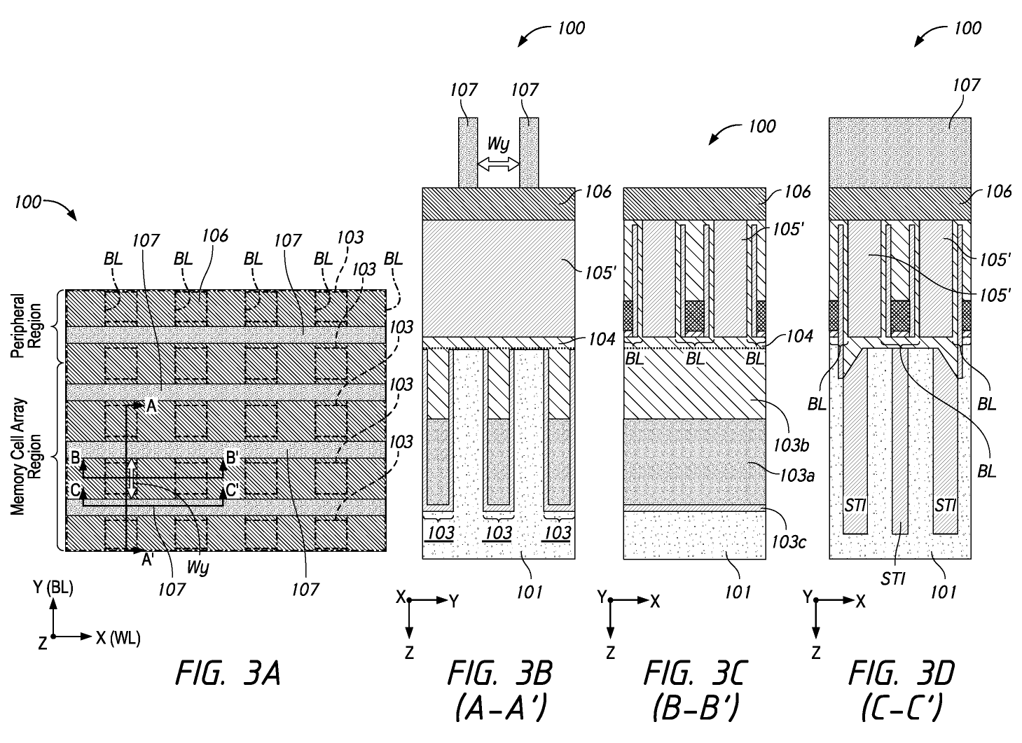

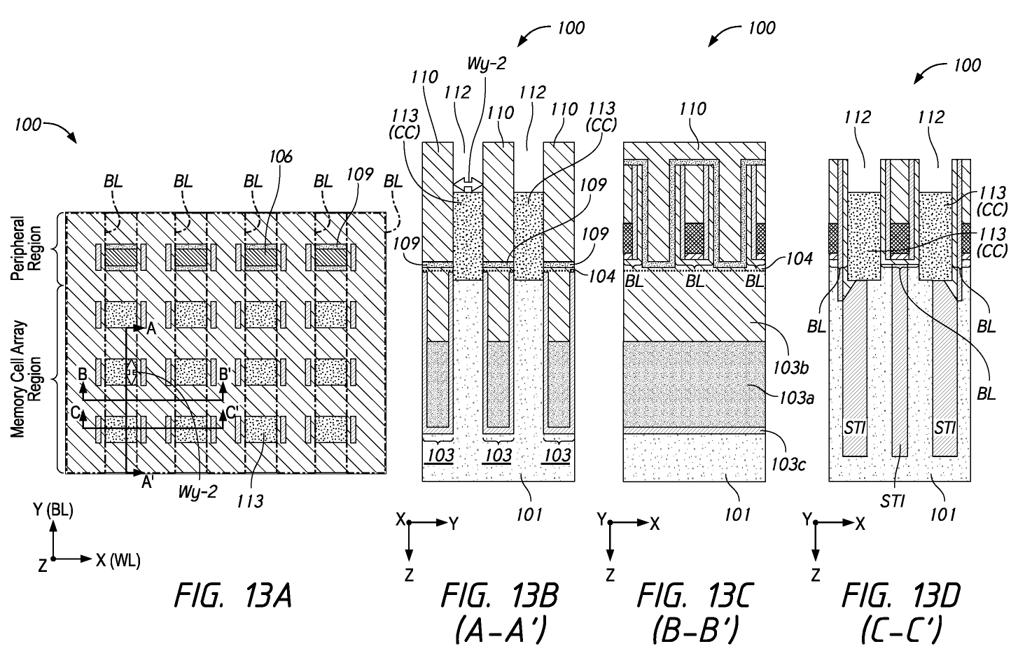

As shown in FIGS. 3A-3D, as part of cell contact formation, a silicon oxide (SiO) layer 106 is provided on the plurality of bit line structures BL and the plurality of oxide-filled gaps/spaces 105’ by for example deposition, and a hard mask 107 is provided in a line-and-space pattern on the SiO layer 106. The hard mask 107 may include for example carbon. Any conventional processes as well as conventional materials may be applicable for the provision of the oxide layer and the hard mask as appropriate. In the depicted example, the line-and-space pattern of the hard mask 107 has lines and spaces arranged in parallel in the Y-axis direction and each extend in the X-axis direction. The line-and-space pattern of the hard mask 107 is orthogonal (or substantially orthogonal) to the plurality of bit line structures BL. The lines of the hard mask 107 each may have a width dimension such that a space or a gap formed between the neighboring lines has a sufficient width Wy (in the Y-axis direction in the drawing) to prevent or mitigate separation defects of the lines. The width dimension may further be such that a cell contact to be formed with polysilicon (which may also be referred to as cell contact poly-Si) at a position corresponding to each of the hard mask lines at a later process (see for example FIGS. 13A-13D to 15A-15D) has a sufficient volume to prevent or mitigate high resistance defects. The dimension of the hard mask in the line-and-space pattern may be predetermined based on device specifications, designs, manufacturing processes, or the like. The hard mask 107 in the line-and-space pattern may define a shape of the to-be-formed cell contact.

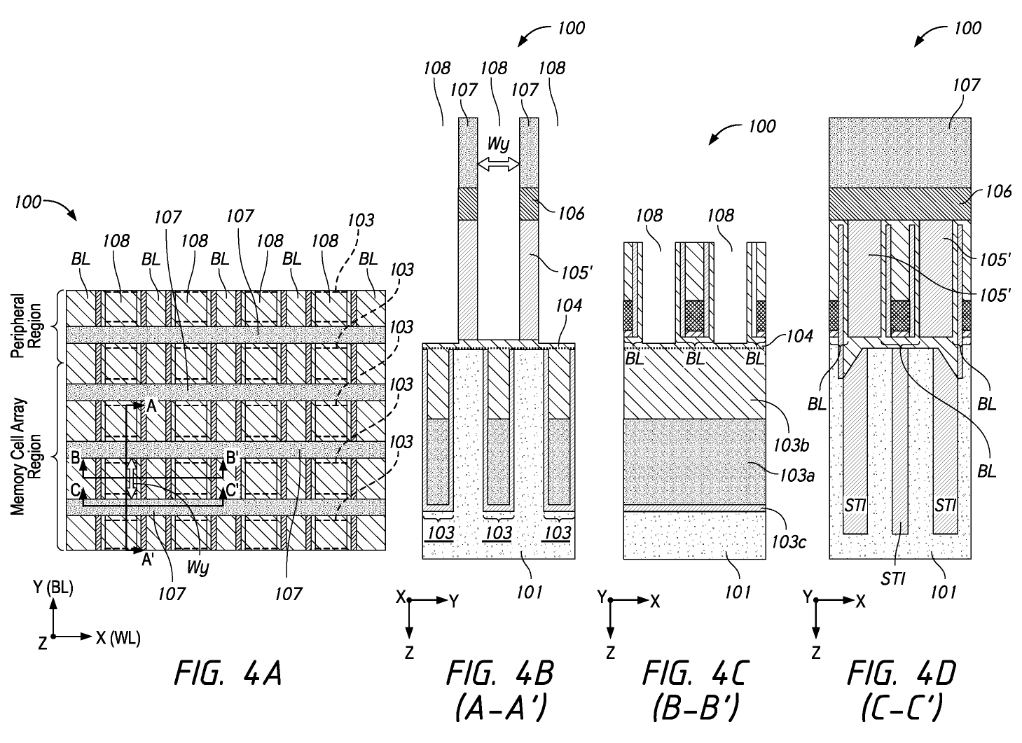

As shown in FIGS. 4A-4D, as part of cell contact formation, part of the SiO layer 106 and part of the oxide-filled gaps/spaces 105’ not covered by the hard mask 107 are removed by for example dry etching. A top surface of the insulating layer 104 may also be etched. The remaining parts of the SiO layer 106 and the oxide-filled gaps/spaces 105’ form a line-and-space pattern that reflects the line-and-space pattern of the hard mask 107. The line-and-space pattern formed has a shape and a size corresponding to the line-and-space pattern of the hard mask 107. For example, a space or a gap 108 formed between the neighboring lines has the same or substantially the same width as Wy.

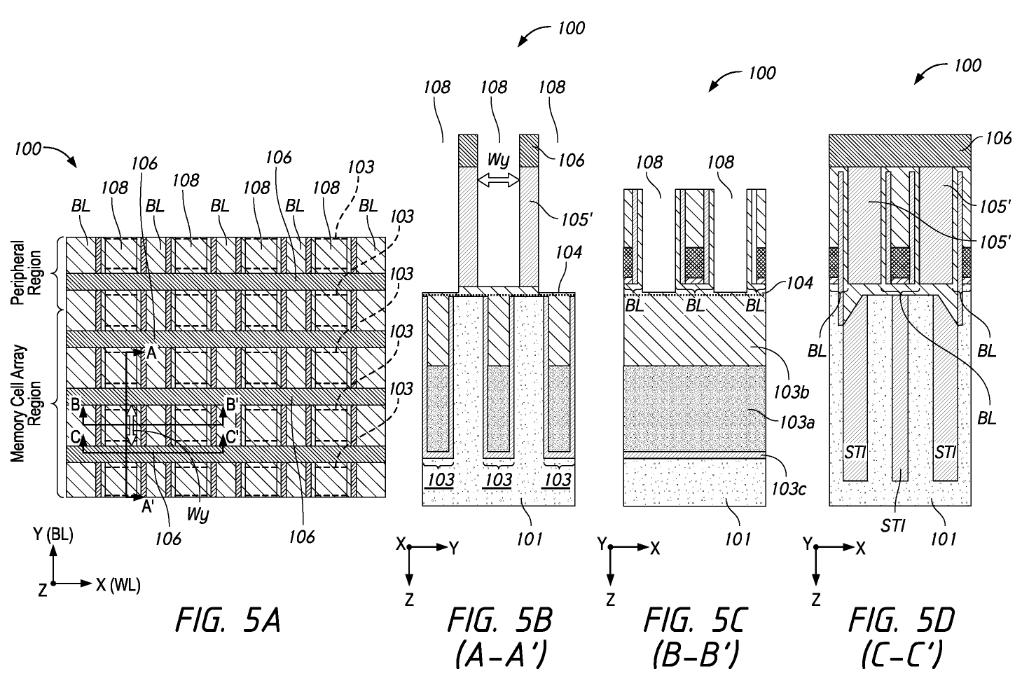

As shown in FIGS. 5A-5D, as part of cell contact formation, the hard mask 107 is removed by for example dry etching. The top surface of the insulating layer 104 may be further etched, and the remaining insulating layer 104 may become thinner. The exposed surfaces may then be cleaned. Each space/gap 108 still has the same or substantially the same width as Wy.

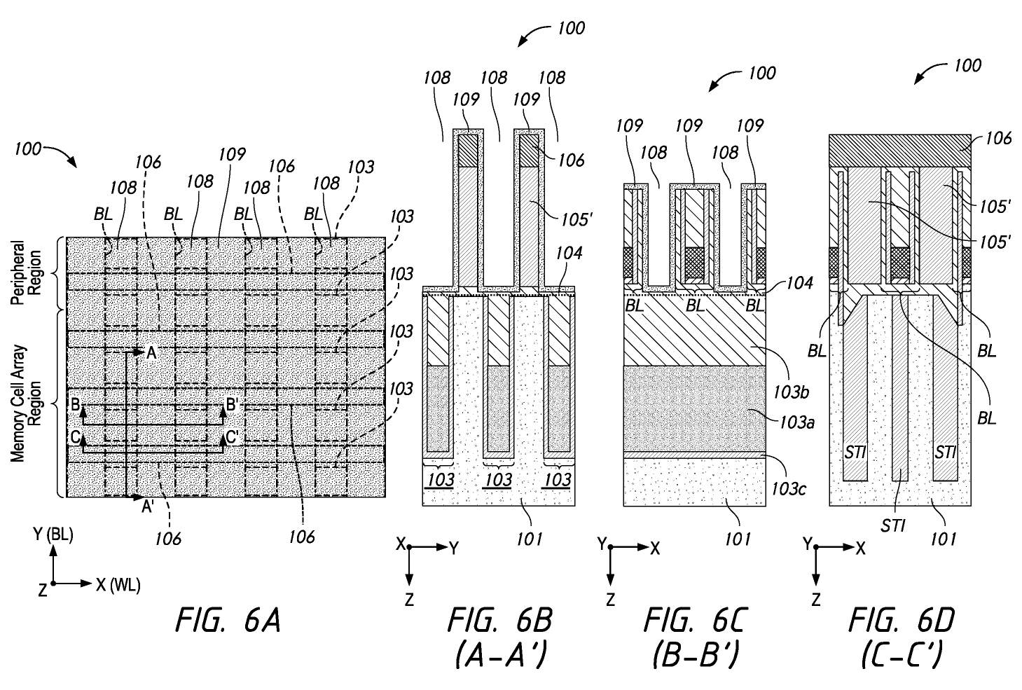

As shown in FIGS. 6A-6D, as part of cell contact formation, a sacrificing layer 109 is provided to the space/gap 108 by for example deposition. In the depicted example, the sacrificing layer 109 is provided on the exposed surfaces of the lines of the SiO layer 106 and the oxide-filled gaps/spaces 105’. The sacrificing layer 109 may also cover the exposed top surface of the insulating layer 104. The sacrificing layer 109 may include, for example, silicon oxycarbide (SiOC) or silicon oxycarbonitride (SiOCN).

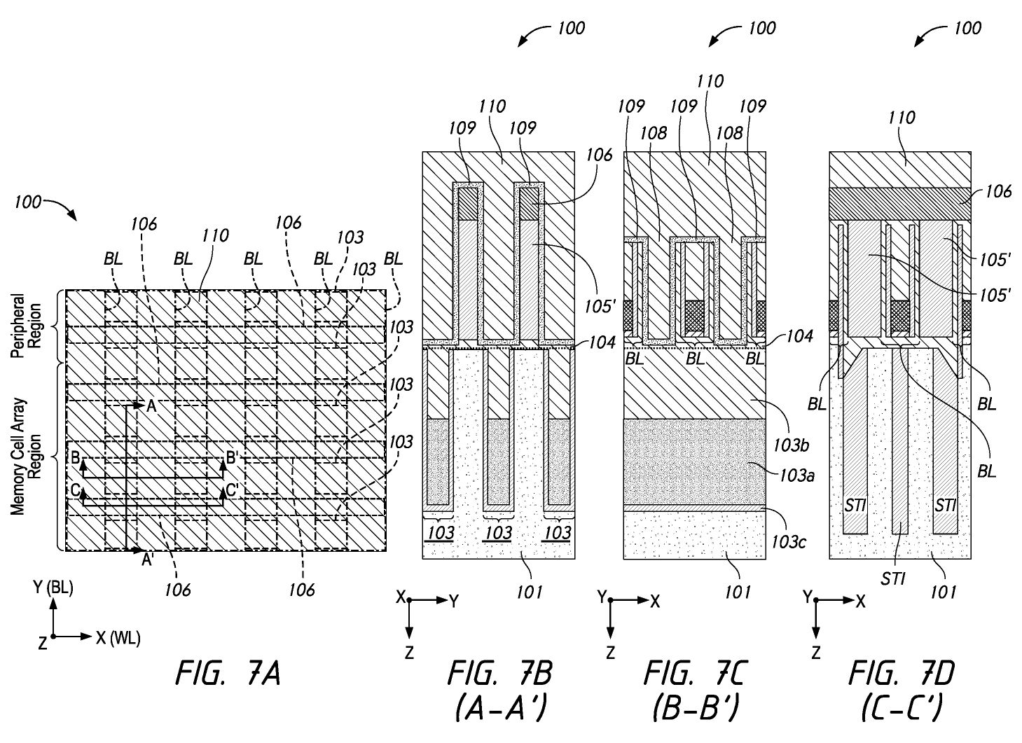

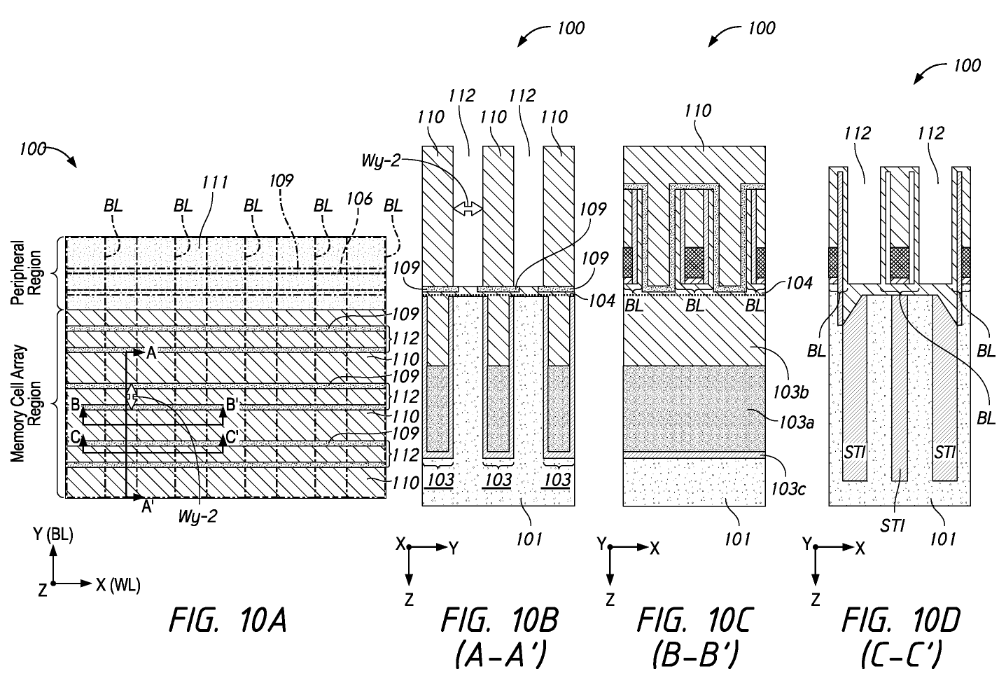

As shown in FIGS. 7A-7D, as part of cell contact formation, a silicon nitride (SiN) layer 110 is provided on the sacrificing layer 109 by for example deposition. The SiN layer 110 at least fills the space/gap 108 covered by the sacrificing layer 109. In the present embodiments, the sacrificing layer 109 may be a first part/layer to be used for cell contact separation, and the SiN layer 110 may be a second part/layer to be used for cell contact separation. Therefore, the method according to the present embodiments applies the bi-layer or two-layer gap fill process to the space/gap 108. As for the first layer, a first material, such as SiOC and SiOCN, that has low etching resistance during a later process of etching in the memory cell array region (see for example FIGS. 10A-10D) is used. As for the second layer, a second material, such as SiN, that has high etching resistance during the later process of etching in the memory cell array region is used. By using such a bi-layer gap fill process or a bi-layer structure for cell contact separation, it is possible to lower an aspect ratio of a line-and-space pattern to be formed by etching (see for example FIGS. 5A-5D to FIGS. 6A-6D) to obtain the same cell size as that in a case where such a bi-layer gap fill process or structure for cell contact separation is not utilized. In some embodiments, part of the first layer/the sacrificing layer 109 may remain in the peripheral region (including for example a dummy region) and in part of an array pattern in the memory cell array region as a final structure.

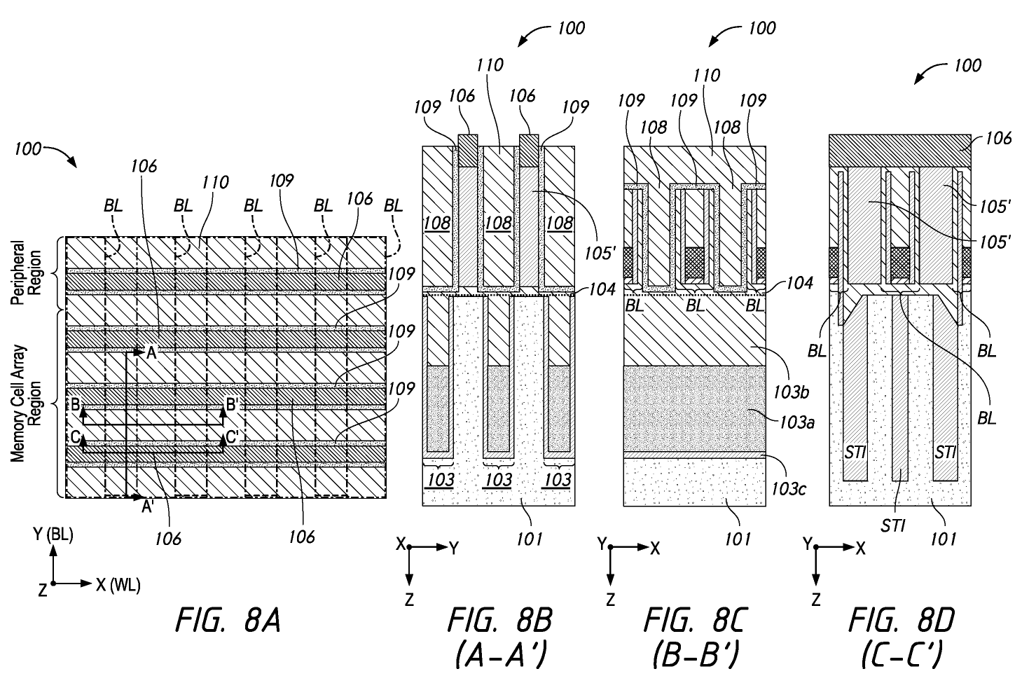

As shown in FIGS. 8A-8D, as part of cell contact formation, at least a top part of the SiN layer 110 and at least a top part of the sacrificing layer 109 are removed by for example dry etching or dry etch back. This reveals at least a top part of the SiO layer 106.

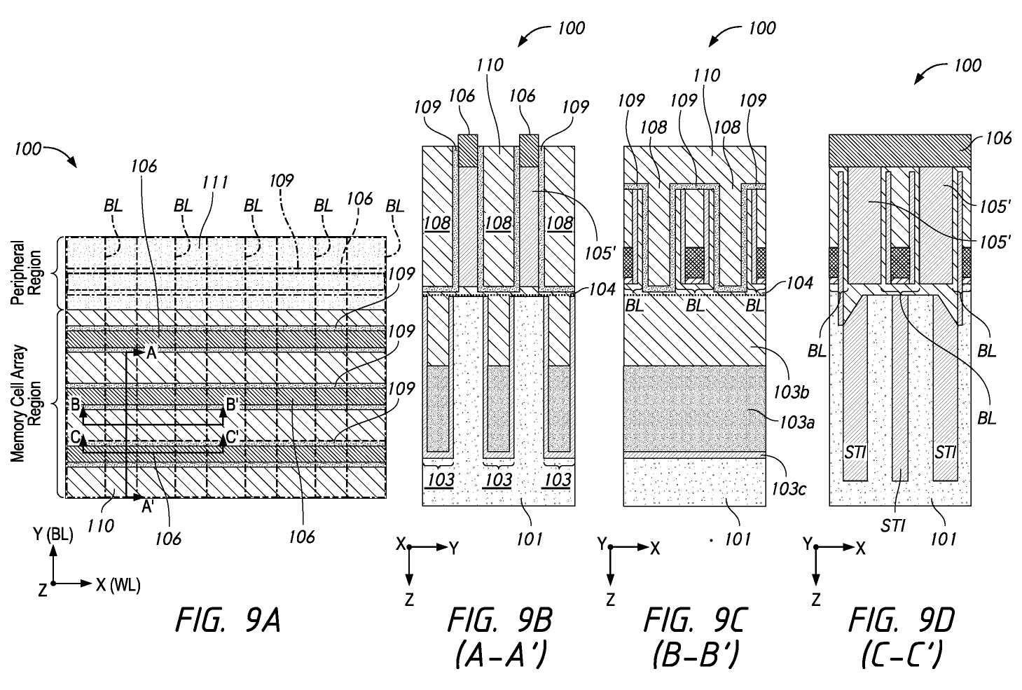

As shown in FIGS. 9A-9D, as part of cell contact formation, a photoresist 111 is provided on an area that is not to be etched at a later process of wet etching (see FIGS. 10A-10D). The area includes at least part of the peripheral region adjacent to the memory cell array region. In some embodiments, the part of the peripheral region may include a dummy region where a cell contact is not formed and hence a dummy pattern is formed that does not work as a memory cell. The photoresist 111 may include for example carbon. Any conventional processes as well as conventional photoresist materials may be applicable as appropriate.

As shown in FIGS. 10A-10D, as part of cell contact formation, the oxide layers/portions including the SiO layer 106, the oxide-filled gaps/spaces 105’ and the sacrificing layer 109 (e.g., SiOC and SiOCN) in the area not covered by the photoresist 111 are removed by wet etching in the memory cell array region. This array etching creates cell contact holes 112 in the remaining SiN layer 110 in the memory cell array region. The cell contact holes 112 each extend in a vertical direction (which may be for example a Z-axis direction in the drawing) and are separated from each other by the remaining portions of the SiN layer 110. The remaining portions of the SiN layer 110 thus become separation lines of the cell contact holes 112 and hence of cell contacts that will be formed in the cell contact holes 112 at a later process (see for example FIGS. 13A-13D to 15A- 15D ). Each of the cell contacts hole 112 may have a sufficient width Wy-2 in the Y-axis/bit line direction to effectively decrease resistance of the to-be-formed cell contact. The target value of Wy-2 may be predetermined based on device specifications, designs, manufacturing processes, or the like. In some embodiments, a width of each line of the hard mask 107 (see for example FIGS. 3B and 4B) and a width of the sacrificing layer 109 (see for example FIG. 6B) in the Y-axis/bit line direction may be predetermined to achieve the predetermined value of Wy-2 of the cell contact hole 112. Such hard mask and sacrificing layer may define Wy-2 of the cell contact hole 112. Any conventional wet etching processes as well as wet etching chemicals may be applicable for removal of target oxides and creation of the cell contact hole 112 as appropriate; however, conditions, chemicals, or the like of wet etching may be predetermined to leave the cell contact hole 112 having Wy-2 in the SiN layer 110. In the depicted example, part of the sacrificing layer 109 may remain at the bottom of each cell contact hole 112.

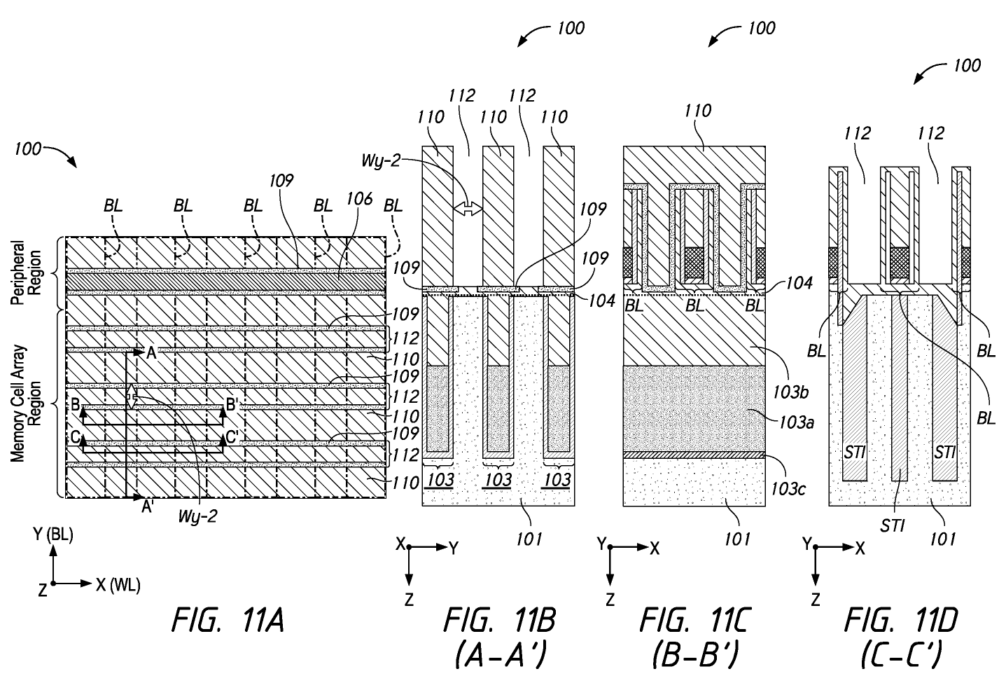

As shown in FIGS. 11A-11D, as part of cell contact formation, the photoresist 111 is removed from the peripheral region. The removal of the photoresist 111 reveals the line of the SiO layer 106 (and the oxide-filled gap/space 105’ under the SiO layer 106) covered by the sacrificing layer 109 in the peripheral region because the line was protected by the photoresist 111 and was not etched by the wet etching during the previous process.

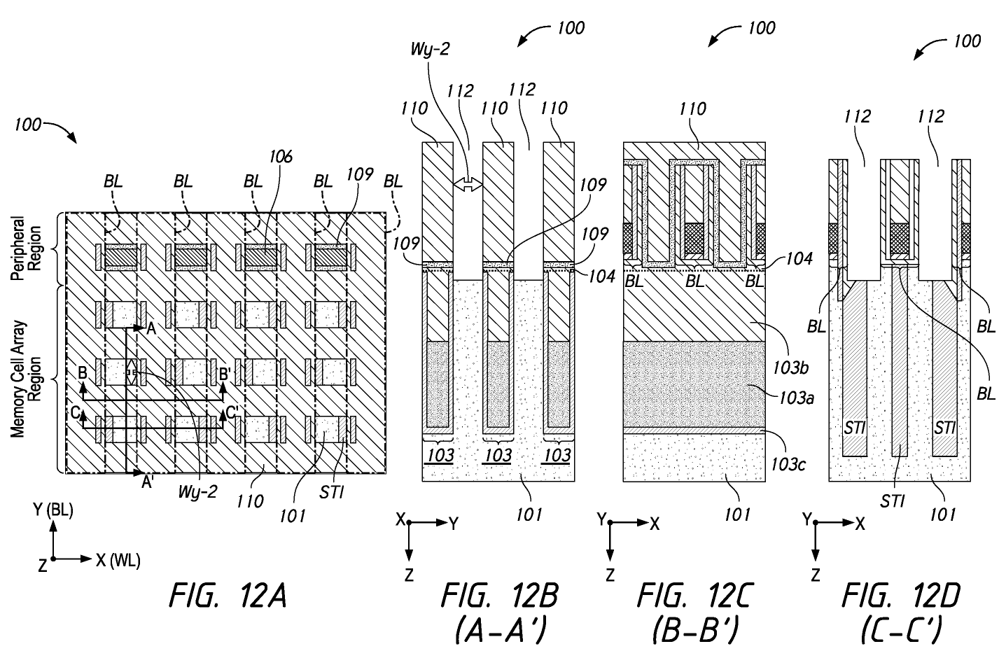

As shown in FIGS. 12A-12D, as part of cell contact formation, each of the cell contact holes 112 are made deeper in the vertical direction by for example dry etching. In the depicted example, part of the insulating layer 104 and part of the sacrificing layer 109 exposed at the bottom of each of the cell contact holes 112 are removed. Part of the semiconductor substrate 101 is also removed. With this process, a bottom portion of each cell contact hole 112 reaches partway through the semiconductor substrate 101. The patterns formed in advance at the respective STIs and active regions in the semiconductor substrate 101 are revealed. In the depicted example, these patterns are represented with a rectangular form in FIG. 12A; however, in some embodiments, the patterns may have a rectangular shape with rounded corners, a circular shape, an oval shape, or the like.

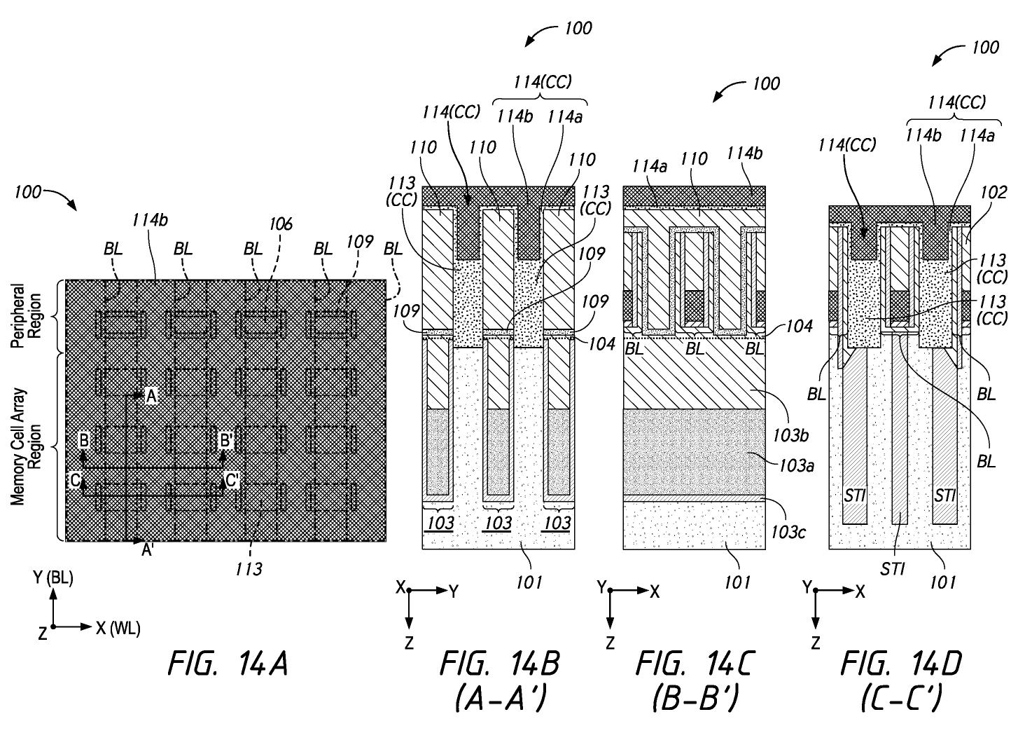

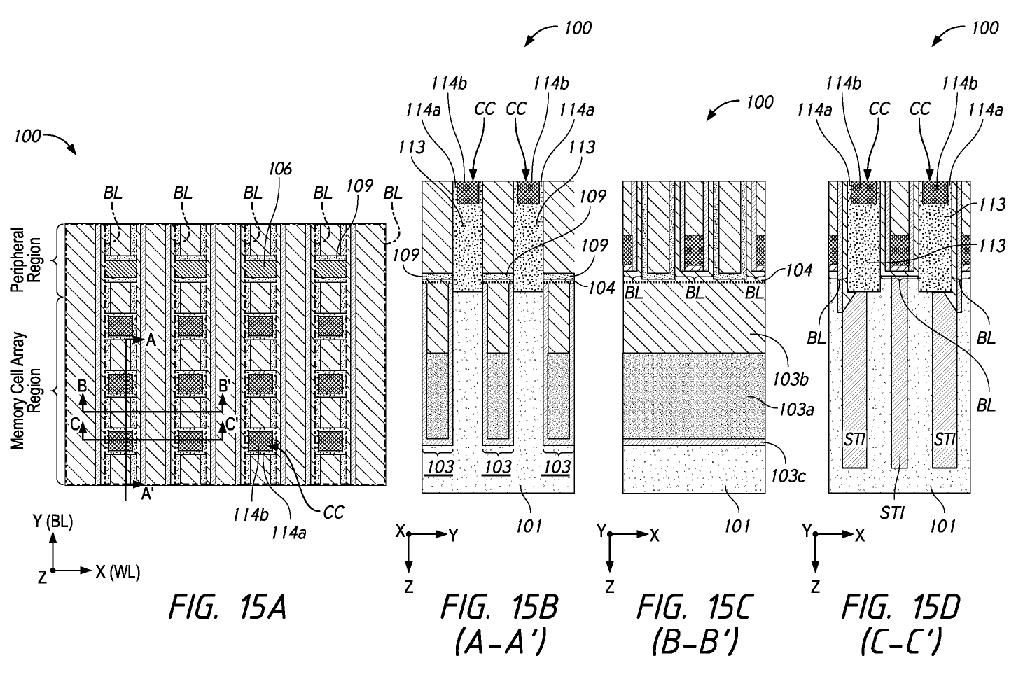

Finally, as shown in FIGS. 13A-13D to FIGS. 15A-15D, cell contacts CC are formed in the cell contact holes 112. First, as shown in FIGS. 13A-13D, polysilicon or cell contact poly-Si 113 is provided to each of the cell contact holes 112 by for example deposition to form at least a lower part of the cell contact CC in the contact hole 112. Since the contact hole 112 has the sufficient width Wy-2, the sufficient volume of poly-Si can be obtained to prevent or mitigate high resistance defects and hence to secure appropriate read and write operations. Second, as shown in FIGS. 14A-14D, cell contact metal 114 is provided on the cell contact poly-Si 113 by for example deposition to form at least an upper part of the cell contact CC. The cell contact metal 114 may include for example TiN and W. In the depicted example, TiN 114a is first provided to the exposed side surfaces of the cell contact hole 112 and on the top surface of the cell contact poly-Si 113, and then, the remaining gap of the cell contact hole 112 is filled with W 114b. Third, as shown in FIGS. 15A-15D, the exposed top portions of the cell contact metal 114 and the SiN layer 110 are removed by for example CMP.

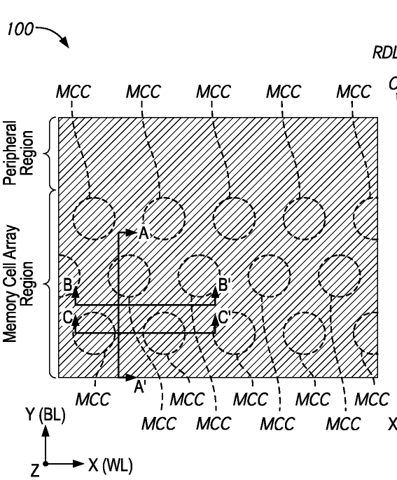

After the cell contacts CC are formed as described above, as shown in FIGS. 16A-16D, redistribution layers RDL and memory cell capacitors MCC are formed. Any conventional processes and materials may be applicable as appropriate. The redistribution layers RDL are formed to couple the cell contacts CC to the corresponding memory cell capacitors MCC. The redistribution layers RDL are coupled to the cell contacts CC and the memory cell capacitors MCC at upper ends and lower ends, respectively. The redistribution layers RDL may include a conductive material, such as W. The memory cell capacitors MCC are formed in the memory cell array region. The memory cell capacitors MCC may include a conductive material, such as TiN, Adjacent to the memory cell capacitors MCC are high-k films 120. The high-k films 120 may include a high-k dielectric material, such as hafnium oxide (HfO). In the depicted example, insulating layers 121 and 122 are also provided. The insulating layers 121 and 122 may include an insulating material, such as SiN. Another conductive layer 123 including a conductive material such as TiN may also be provided. In the resultant structure, the memory cell capacitors MCC are coupled to the active regions of the semiconductor substrate 101 by way of the associated cell contacts CC and redistribution layers RDL.

Accordingly, the present embodiments provide the methods that utilize the bi-layer gap fill process to effectively achieve sufficient separation of the cell contacts in the memory cell array region while at the same time achieving a sufficient volume of the cell contact poly-Si and hence a sufficient cell contact size to prevent or mitigate defects due to high resistance of the cell contacts. This can secure appropriate read and write operations while realizing chip or device downsizing.

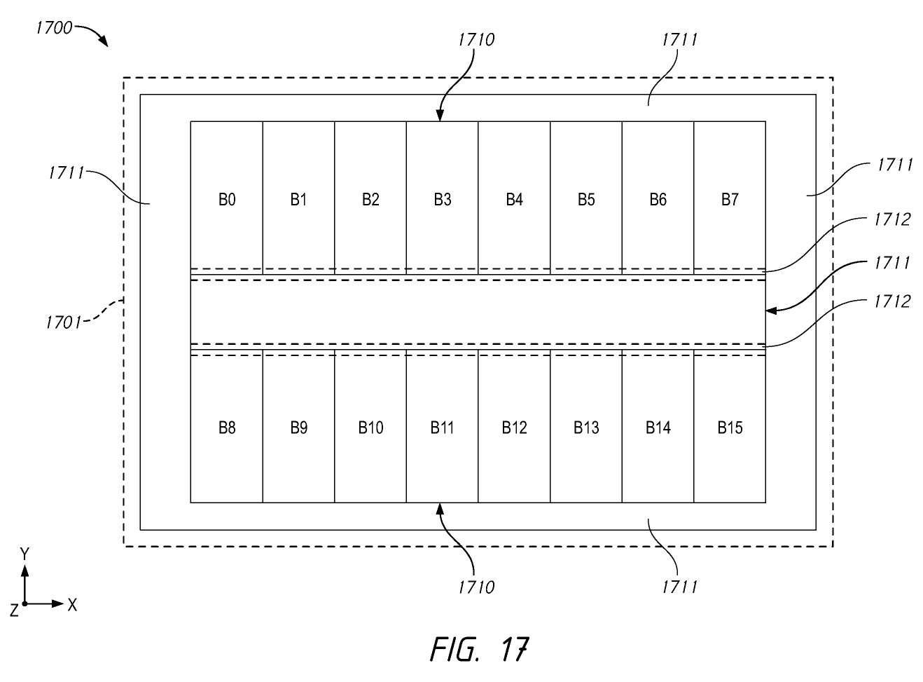

FIG. 17 depicts an example of a block diagram of a memory device 1700 in a plan view according to some embodiments of the disclosure. The memory device 1700 may be one example of a semiconductor device. The memory device 1700 may be one example of an apparatus. The memory device 1700 may be a DRAM. The memory device 1700 includes one or more memory regions 1710 and one or more peripheral regions 1711. The memory regions 1710 include a plurality of memory banks of memory cells. In the depicted example, the memory device 1700 includes a pair of the memory regions 1710 arranged in two rows that are extending in one horizontal direction, which may be for example an X-axis direction in the drawing, and neighboring with each other in another horizontal direction, which may be for example a Y-axis direction perpendicular or substantially perpendicular to the X-axis direction in the drawing. The memory regions 1710 of the pair include, respectively, a first group of memory banks BANK0-BANK7 (B0-B7) and a second group of memory banks BANK8-BANK15 (B8-B15). The memory banks in each group are arranged next to each other in the corresponding row. The memory banks may be accessed to read data from and write data to the memory cells. In the depicted example, one peripheral region 1711 is provided between the memory regions 1710. The peripheral region 1711 is adjacent to the memory regions 1710 with boundaries or boundary regions 1712 therebetween. Regions around the memory regions 1710 may also be the peripheral regions 1711 including boundaries or boundary regions with the neighboring memory regions 1710. Various circuits and circuit elements (for example, transistors) that are used for memory operations are included in the peripheral regions 1711. Such circuits and circuit elements in the peripheral regions 1711 are coupled to the memory cells in the memory regions 1710 by, for example, conductive wirings, wiring layers, and conductive contacts. The number, the position, the arrangement and such of the memory regions 1710 are not limited to the examples and the embodiments described herein. The number, the position, the arrangement and such of the memory banks and/or the memory cells are not limited to the examples and the embodiments described herein. The number, the position, the arrangement and such of the peripheral regions 1710 are not limited to the examples and the embodiments described herein. The memory regions 1710 and the peripheral regions 1711 are formed on a semiconductor substrate 1701. In some embodiments, the memory regions 1710 and the peripheral regions 1711 may correspond to the memory cell array region and the peripheral region, respectively, in FIGS. 1A-1D to 16A-16D.

DRAM is merely one example, and the embodiments and the descriptions herein are not intended to be limited to DRAM. Memory devices other than DRAM, such as a static random-access memory (SRAM), a flash memory, an erasable programmable read-only memory (EPROM), a magnetoresistive random-access memory (MRAM), and a phase-change memory, can also be applied as the apparatuses of the present embodiments. Furthermore, devices other than memory, including logic ICs, such as a microprocessor and an application-specific integrated circuit (ASIC), are also applicable as the apparatuses according to the present embodiments.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still falling within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. A method, comprising forming two layers in a plurality of gaps for separation of cell contacts in a memory device, wherein the two layers include a first layer on surfaces of the gaps and a second layer on the first layer, the second layer filling the gaps covered by the first layer.

2. The method according to claim 1, wherein the first layer is a sacrificing layer.

3. The method according to claim 1, wherein the first layer includes a material that has a low etching resistance during a process of etching as part of cell contact formation in a memory cell array region.

4. The method according to claim 1, wherein the first layer includes silicon oxycarbide (SiOC).

5. The method according to claim 1, wherein the first layer includes silicon oxycarbonitride (SiOCN).

6. The method according to claim 1, wherein the second layer includes a material that has a high etching resistance during a process of etching as part of cell contact formation in a memory cell array region.

7. The method according to claim 1, wherein the second layer includes silicon nitride (SiN).

8. The method according to claim 1, wherein
the method further comprises forming the plurality of gaps on a semiconductor substrate, and
forming the two layers include:
providing the first layer on the surfaces of each of the gaps; and
providing the second layer on the first layer to fill each of the gaps covered by the first layer.

9. The method according to claim 8, wherein the method further comprises:
providing a mask in a line-and-space pattern; and
removing an area not covered by the mask to form the gaps.

10. The method according to claim 9, wherein lines of the hard mask in the line-and-space pattern each have a width dimension such that a space formed between neighboring lines has a width to prevent or mitigate a separation defect of the lines.

11. The method according to claim 10, wherein the width dimension is further such that a cell contact to be formed with polysilicon at a position corresponding to each of the lines at a later process has a volume to prevent or mitigate a high resistance defect.

12. The method according to claim 8, wherein the line-and-space pattern of the mask is orthogonal to a plurality of bit lines.

13. The method according to claim 1, further comprising:
forming a plurality of bit line structures in a memory cell array region and a peripheral region adjacent to the memory cell array region;
providing a hard mask in a line-and-space pattern, the line-and-space pattern orthogonal to the bit line structures;
forming the plurality of gaps that correspond to spaces of the line-and-space pattern of the hard mask;
providing the first layer as a sacrificing layer to cover the surfaces of the gaps; and
providing the second layer on the first layer to fill the gaps.

14. The method according to claim 1, further comprising:
forming a plurality of cell contact holes separated from each other by the second layer; and
forming a plurality of cell contacts in the cell contact holes, the cell contacts separated from each other by the second layer.

15. The method according to claim 14, further comprising:
forming redistribution layers coupled to the cell contacts; and
forming cell capacitors coupled to the redistribution layers.

16. A method, comprising:
forming a plurality of bit line structures in a memory cell array region and a peripheral region adjacent to the memory cell array region;
providing a hard mask in a line-and-space pattern, the line-and-space pattern orthogonal to the bit line structures;
forming a plurality of gaps that correspond to spaces of the line-and-space pattern of the hard mask;
forming two layers in the plurality of gaps for separation of cell contacts, wherein
the two layers include a first layer on surfaces of each of the gaps and a second layer on the first layer, the second layer filling each of the gaps covered by the first layer,
the first layer includes silicon oxycarbide (SiOC) or silicon oxycarbonitride (SiOCN); and
the second layer includes silicon nitride (SiN).

17. The method according to claim 16, further comprising:
forming a plurality of cell contact holes separated from each other by the second layer in the memory cell array region; and
forming a plurality of cell contacts in the cell contact holes in the memory cell array region, the cell contacts separated from each other by the second layer.

18. The method according to claim 17, further comprising:
forming redistribution layers coupled to the cell contacts; and
forming cell capacitors coupled to the redistribution layers.

19. The method according to claim 16, wherein the method further comprises:
providing a mask in a line-and-space pattern; and
removing an area not covered by the mask to form the gaps, wherein
lines of the hard mask in the line-and-space pattern each have a width dimension such that a space formed between neighboring lines has a width to prevent or mitigate a separation defect of the lines and such that a cell contact to be formed with polysilicon at a position corresponding to each of the lines at a later process has a volume to prevent or mitigate a high resistance defect.

20. A method for forming cell contacts of a memory device, comprising:
forming a plurality of gaps on a semiconductor substrate in a memory cell array region and a peripheral region adjacent to the memory cell array region;
forming two layers in the plurality of gaps, including:
providing a first layer on surfaces of each of the gaps; and
providing a second layer on the first layer to fill each of the gaps covered by the first layer;
forming a plurality of cell contact holes in the memory cell array region, the cell contact holes separated from each other by the second layer; and
forming a plurality of cell contacts in the cell contact holes in the memory cell array region, the cell contacts separated from each other by the second layer.
